(19) United States
(12) Patent Application Publication
(10) Pub. No.: US 2024/0332428 A1
(43) Pub. Date: Oct. 3, 2024

(54) SEMICONDUCTOR DEVICE AND DISPLAY DEVICE

(71) Applicant: Japan Display Inc., Tokyo (JP)

(72) Inventors: Masahiro WATABE, Minato-ku (JP); Masashi TSUBUKU, Minato-ku (JP); Hajime WATAKABE, Minato-ku (JP); Toshinari SASAKI, Minato-ku (JP); Marina MOCHIZUKI, Minato-ku (JP); Takaya TAMARU, Minato-ku (JP); Ryo ONODERA, Minato-ku (JP)

(73) Assignee: Japan Display Inc., Tokyo (JP)

(21) Appl. No.: 18/617,858

(22) Filed: Mar. 27, 2024

(30) Foreign Application Priority Data
Mar. 28, 2023 (JP) 2023-050865

(51) Int. Cl. H01L 29/786; H01L 27/12; H01L 29/423

(52) U.S. Cl. CPC H01L 29/7869; H01L 27/1248; H01L 29/42384

(57) ABSTRACT

A semiconductor device comprises a first insulating layer; a metal oxide layer mainly composed of aluminum on the first insulating layer; an oxide semiconductor layer having a polycrystalline structure on the metal oxide layer; a gate insulating layer on the oxide semiconductor layer; a gate electrode on the gate insulating layer; and a second insulating layer on the gate electrode. The metal oxide layer and the oxide semiconductor layer are both patterned, and the oxide semiconductor layer has a first region in contact with the gate insulating layer and a second region continuous with the first region in a first direction and in contact with the gate insulating layer and the second insulating layer.

### CROSS REFERENCE TO RELATED APPLICATIONS

This application claims the benefit of priority to Japanese Patent Application No. 2023-050865, filed on Mar. 28, 2023, the entire contents of which are incorporated herein by reference.

### FIELD

An embodiment of the present invention relates to a semiconductor device and a display device. In particular, an embodiment of the present invention relates to a semiconductor device containing an oxide semiconductor and a display device using the semiconductor device containing an oxide semiconductor.

### BACKGROUND

In recent years, an oxide semiconductor, instead of amorphous silicon, polysilicon, and single-crystal silicon, has attracted attention as a constituent material of a semiconductor device. In particular, a thin film transistor using an oxide semiconductor as a channel has been developed as a semiconductor device containing an oxide semiconductor (see, for example, Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The thin film transistor using the oxide semiconductor as the channel can be formed in a simple-structure and low-temperature process, similar to a semiconductor device using amorphous silicon as the channel. The thin film transistor using the oxide semiconductor as the channel is known to have higher field-effect mobility than the thin film transistor using amorphous silicon as the channel.

### SUMMARY

A semiconductor device in one embodiment of the invention comprises a first insulating layer; a metal oxide layer mainly composed of aluminum on the first insulating layer; an oxide semiconductor layer having a polycrystalline structure on the metal oxide layer; a gate insulating layer on the oxide semiconductor layer; a gate electrode on the gate insulating layer; and a second insulating layer on the gate electrode. The metal oxide layer and the oxide semiconductor layer are both patterned, and the oxide semiconductor layer has a first region in contact with the gate insulating layer and a second region continuous with the first region in a first direction and in contact with the gate insulating layer and the second insulating layer.

### BRIEF DESCRIPTION OF THE DRAWINGS

FIG. 1 is a schematic cross-sectional view showing a configuration of a semiconductor device according to an embodiment of the present invention.

FIG. 2 is a schematic plan view showing a configuration of a semiconductor device according to an embodiment of the present invention.

FIG. 3 is a sequence diagram showing a method for manufacturing a semiconductor device according to an embodiment of the present invention.

FIG. 4 is a cross-sectional view showing a method for manufacturing a semiconductor device according to an embodiment of the present invention.

FIG. 5 is a cross-sectional view showing a method for manufacturing a semiconductor device according to an embodiment of the present invention.

FIG. 6 is a cross-sectional view showing a method for manufacturing a semiconductor device according to an embodiment of the present invention.

FIG. 7 is a cross-sectional view showing a method for manufacturing a semiconductor device according to an embodiment of the present invention.

FIG. 8 is a cross-sectional view showing a method for manufacturing a semiconductor device according to an embodiment of the present invention.

FIG. 9 is a cross-sectional view showing a method for manufacturing a semiconductor device according to an embodiment of the present invention.

FIG. 10 is a cross-sectional view showing a method for manufacturing a semiconductor device according to an embodiment of the present invention.

FIG. 11 is a cross-sectional view showing a method for manufacturing a semiconductor device according to an embodiment of the present invention.

FIG. 12 is a cross-sectional view showing a method for manufacturing a semiconductor device according to an embodiment of the present invention.

FIG. 13 is a sequence diagram showing a method for manufacturing a semiconductor device according to an embodiment of the present invention.

FIG. 14 is a plan view showing a schematic configuration of a display device according to an embodiment of the present invention.

FIG. 15 is a block diagram showing a circuit configuration of a display device according to an embodiment of the present invention.

FIG. 16 is a circuit diagram showing a pixel circuit of a display device according to an embodiment of the present invention.

FIG. 17 is a cross-sectional view showing a configuration of a display device according to an embodiment of the present invention.

FIG. 18 is a plan view showing a pixel electrode and a common electrode of a display device according to an embodiment of the present invention.

FIG. 19 is a circuit diagram showing a pixel circuit of a display device according to an embodiment of the present invention.

FIG. 20 is a schematic cross-sectional view showing a configuration of a display device according to an embodiment of the present invention.

FIG. 21A shows the electrical characteristics of a semiconductor device of an embodiment of the present invention.

FIG. 21B shows the electrical characteristics of a semiconductor device of a comparative example.

FIG. 22 shows an example of a relationship of channel resistance (R) to the design channel length (channel length on layout) (Lg) of the transistor for different gate voltages (Vg).

FIG. 23A shows a dependence of a threshold voltage on a channel length in a semiconductor device of an embodiment of the present invention.

FIG. 23B shows a dependence of a threshold voltage on a channel length in a semiconductor device of a comparative example.

### DESCRIPTION OF EMBODIMENTS

However, a threshold voltage indicating switching characteristics may be shifted in a negative direction, or a variation in the threshold voltage may be increased when a channel length decreases in a conventional thin film transistor containing an oxide semiconductor. For this reason, the conventional thin film transistor containing an oxide semiconductor has low flexibility in designing the channel length in order to reduce the size.

An object of the present invention is to improve the electrical characteristics of a semiconductor device containing an oxide semiconductor.

Hereinafter, embodiments of the present invention will be described with reference to the drawings. The following disclosure is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the width, thickness, shape, and the like of each part in comparison with an actual embodiment. However, the illustrated shapes are merely examples, and do not limit the interpretation of the present invention. In the present specification and the drawings, the same reference signs are given to elements similar to those described above with respect to the above-described drawings, and detailed description thereof may be omitted as appropriate.

In the embodiments of the present invention, a direction from a substrate toward an oxide semiconductor layer is referred to as upper or above. Conversely, a direction from the oxide semiconductor layer to the substrate is referred to as lower or below. In this way, for convenience of explanation, the phrase “above” or “below” is used for description, but for example, the upper and lower relationship between the substrate and the oxide semiconductor layer may be opposite to those shown in the drawings. In the following explanation, for example, the expression “oxide semiconductor layer on substrate” merely describes the upper and lower relationship between the substrate and the oxide semiconductor layer as described above, and another member may be arranged between the substrate and the oxide semiconductor layer. The terms above and below refer to a stacking order in which a plurality of layers is stacked, and when expressed as “a pixel electrode above a transistor” this expression may refer to a positional relationship in which the transistor and the pixel electrode do not overlap each other in a plan view. On the other hand, the expression “a pixel electrode vertically above a transistor” means a positional relationship in which the transistor and the pixel electrode overlap each other in a plan view.

“Display device” refers to a structure that displays an image using an electro-optic layer. For example, the term display device may refer to a display panel including the electro-optic layer or a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, and an electrophoretic layer, unless there is no technical contradiction. Therefore, a liquid crystal display device including the liquid crystal layer, and an organic EL display device including an organic EL layer are exemplified as the display device in the embodiments described later, but the structure according to the present embodiment can be applied to a display device including the other electro-optical layers described above.

In this specification, the expressions “a includes A, B or C,” “a includes any of A, B or C,” “a includes one selected from a group consisting of A, B and C,” and the like do not exclude the case where a includes a plurality of combinations of A to C unless otherwise indicated. Furthermore, these expressions do not exclude the case where a includes other elements.

In this specification, the “same” includes the case being substantially the same in addition to being exactly the same. “Substantially the same” refers to a case that falls within a range of small differences that are not completely the same but can be considered the same. For example, “substantially the same” refers to the case where the difference between the two values falls within an error of +5% (preferably +3%).

### First Embodiment

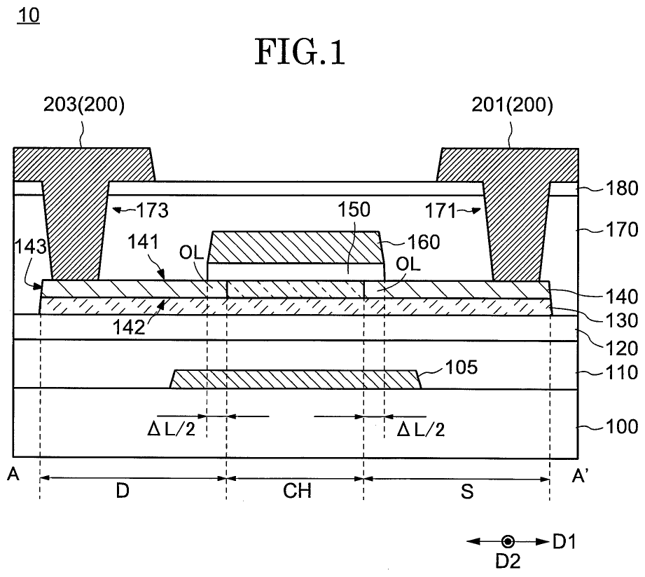

A semiconductor device according to an embodiment of the present invention will be described with reference to FIG. 1 to FIG. 12 by exemplifying a thin film transistor. For example, the semiconductor device shown in the embodiments below may be an integrated circuit (IC) such as a micro-processing unit (MPU) or a thin film transistor used in a memory circuit, in addition to the thin film transistor used in the display device.

### [Configuration of Semiconductor Device]

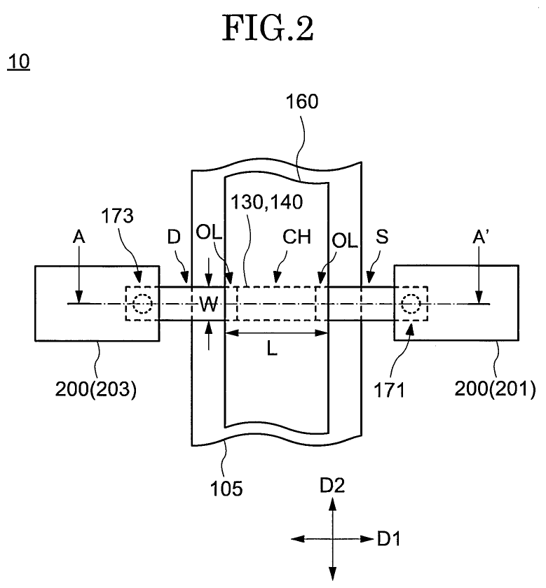

A configuration of a semiconductor device 10 according to an embodiment of the present invention will be described with reference to FIG. 1 and FIG. 2. FIG. 1 is a schematic cross-sectional view showing a configuration of the semiconductor device 10 according to an embodiment of the present invention. FIG. 2 is a schematic plan view showing a configuration of the semiconductor device 10 according to an embodiment of the present invention. Specifically, FIG. 1 corresponds to a cross-sectional view cut along a dash-dot line indicated by A-A′ shown in FIG. 2.

The semiconductor device 10 is arranged above a substrate 100, as shown in FIG. 1. The semiconductor device 10 includes a conductive layer 105, insulating layers 110 and 120, a metal oxide layer 130, an oxide semiconductor layer 140, a gate insulating layer 150, a gate electrode 160, insulating layers 170 and 180, a source electrode 201, and a drain electrode 203. In the case where the source electrode 201 and the drain electrode 203 are not particularly distinguished from each other, they may be collectively referred to as a source/drain electrode 200.

The conductive layer 105 is arranged on the substrate 100. The conductive layer 105 has a function as a light-shielding film for the oxide semiconductor layer 140.

The insulating layers 110 and 120 are arranged on the substrate 100 and the conductive layer 105. The insulating layer 110 functions as a barrier film that shields impurities that diffuse from the substrate 100 toward the oxide semiconductor layer 140.

The metal oxide layer 130 is arranged on the insulating layer 120. The metal oxide layer 130 is in contact with the insulating layer 120. The metal oxide layer 130 is a layer containing metal oxide containing aluminum as a main component and has a function as a gas barrier film for shielding a gas such as oxygen or hydrogen.

The oxide semiconductor layer 140 is arranged on the metal oxide layer 130. The oxide semiconductor layer 140 is in contact with the metal oxide layer 130. Within the main surface of the oxide semiconductor layer 140, a surface in contact with the metal oxide layer 130 is referred to as a lower surface 142. The oxide semiconductor layer 140 is patterned. In the present embodiment, the metal oxide layer 130 and the oxide semiconductor layer 140 have the same pattern shape (for example, an island-shaped pattern shape). That is, an end portion of the metal oxide layer 130 and an end portion of the oxide semiconductor layer 140 substantially coincide with each other in the cross-sectional view. Although a configuration in which the metal oxide layer 130 is in contact with the insulating layer 120 and the oxide semiconductor layer 140 is in contact with the metal oxide layer 130 is exemplified in the present embodiment, the configuration is not limited to this configuration. Another layer may be arranged between the metal oxide layer 130 and the oxide semiconductor layer 140.

In addition, although a side surface of the metal oxide layer 130 and a side surface of the oxide semiconductor layer 140 are arranged substantially in a straight line in FIG. 1, the configuration is not limited to this. An angle of the side surface of the metal oxide layer 130 with respect to the main surface of the substrate 100 may be different from an angle of a side surface 143 of the oxide semiconductor layer 140. The cross-sectional shapes of the side surfaces of at least one of the metal oxide layer 130 and the oxide semiconductor layer 140 may be curved.

The gate insulating layer 150 is arranged on the oxide semiconductor layer 140. The gate insulating layer 150 is patterned to have the same shape as the gate electrode 160. That is, the gate insulating layer 150 and the gate electrode 160 have the same pattern shape. Therefore, part of the oxide semiconductor layer 140 (a region not overlapping the gate electrode 160) is not covered with the gate insulating layer 150. In other words, part of the oxide semiconductor layer 140 is exposed from the gate insulating layer 150. The gate insulating layer 150 has a function as a gate insulating layer for a top gate (the gate electrode 160). The gate insulating layer 150 has a function of releasing oxygen by a heat treatment in the manufacturing process.

The gate electrode 160 faces the oxide semiconductor layer 140 via the gate insulating layer 150. The gate insulating layer 150 is arranged between the oxide semiconductor layer 140 and the gate electrode 160. The gate insulating layer 150 is in contact with the oxide semiconductor layer 140. Within the main surface of the oxide semiconductor layer 140, a surface in contact with the gate insulating layer 150 is referred to as an upper surface 141. A surface between the upper surface 141 and the lower surface 142 is referred to as the side surface 143. The gate electrode 160 has a function as a top gate and a light-shielding film for the oxide semiconductor layer 140 of the semiconductor device 10.

The insulating layers 170 and 180 are arranged on the gate insulating layer 150 and the gate electrode 160. In the present embodiment, a stacked structure composed of the insulating layers 170 and 180 may be referred to as a passivation layer. The insulating layers 170 and 180 insulate the gate electrode 160 and the source/drain electrode 200. Arranging the insulating layers 170 and 180 makes it possible to reduce the parasitic capacitance between the gate electrode 160 and the source/drain electrode 200.

In the present embodiment, a silicon oxide layer is used as the insulating layer 170, and a silicon nitride layer is used as the insulating layer 180. Materials of the insulating layers 170 and 180 are preferably, but not limited to, an insulating layer containing at least one layer of hydrogen, as described below. The insulating layer 170 constituting part of the passivation layer is in contact with the gate electrode 160, the gate insulating layer 150 (specifically, a side surface of the gate insulating layer 150), and the oxide semiconductor layer 140, as shown in FIG. 1. Openings 171 and 173 reaching the oxide semiconductor layer 140 are arranged in the insulating layers 170 and 180.

The source electrode 201 is arranged inside the opening 171 arranged in the insulating layers 170 and 180. The source electrode 201 is in contact with the oxide semiconductor layer 140 at the bottom of the opening 171. The drain electrode 203 is arranged inside the opening 173 arranged in the insulating layers 170 and 180. The drain electrode 203 is in contact with the oxide semiconductor layer 140 at the bottom of the opening 173.

An operation of the semiconductor device 10 is controlled mainly by a gate voltage supplied to the gate electrode 160. An auxiliary voltage may be supplied to the conductive layer 105. In other words, the conductive layer 105 may function as the gate electrode by supplying the auxiliary voltage. However, the present embodiment is not limited to this, and the conductive layer 105 may be used simply as a light-shielding film. In the case where the conductive layer 105 is simply used as a light-shielding film, the conductive layer 105 may be floating without being supplied with a specific voltage.

In the present embodiment, although a top-gate transistor in which the gate electrode 160 is arranged above the oxide semiconductor layer 140 is exemplified as the semiconductor device 10, the configuration is not limited to this. For example, the semiconductor device 10 may be a dual-gate transistor using the conductive layer 105 as the gate electrode in addition to the gate electrode 160. In the case where the conductive layer 105 is used as the gate electrode, the insulating layers 110 and 120 function as the gate insulating layer. However, the above configuration is merely an embodiment, and the present invention is not limited to the above configuration.

The pattern shape of the metal oxide layer 130 is the same as the pattern shape of the oxide semiconductor layer 140 in a plan view, as shown in FIG. 2. The lower surface 142 of the oxide semiconductor layer 140 is covered with the metal oxide layer 130 with reference to FIG. 1 and FIG. 2. In particular, in the present embodiment, the entire lower surface 142 of the oxide semiconductor layer 140 is covered with the metal oxide layer 130. A width of the conductive layer 105 is greater than a width of the gate electrode 160 in a direction D1. The direction D1 is a direction connecting the source electrode 201 and the drain electrode 203, and corresponds to a direction in which carriers move. Within the oxide semiconductor layer 140, a length of a channel region CH in the direction D1 is a channel length (L), and a width of the channel region CH in a direction D2 is a channel width (W).

In the present embodiment, although the configuration in which the entire lower surface 142 of the oxide semiconductor layer 140 is covered with the metal oxide layer 130 has been exemplified, the configuration is not limited to this configuration. For example, part of the lower surface 142 of the oxide semiconductor layer 140 may not be in contact with the metal oxide layer 130. For example, the entire lower surface 142 of the oxide semiconductor layer 140 in the channel region CH may be covered with the metal oxide layer 130, and all or part of the lower surface 142 of the oxide semiconductor layer 140 in a source region S and a drain region D may not be covered with the metal oxide layer 130. That is, all or part of the lower surface 142 of the oxide semiconductor layer 140 in the source region S and the drain region D may not be in contact with the metal oxide layer 130. However, part of the lower surface 142 of the oxide semiconductor layer 140 in the channel region CH may not be covered with the metal oxide layer 130, and another part of the lower surface 142 may be in contact with the metal oxide layer 130, in the above configuration.

Although a configuration in which the source/drain electrode 200 does not overlap the conductive layer 105 and the gate electrode 160 in a plan view is exemplified in FIG. 2, the configuration is not limited to this configuration. For example, the source/drain electrode 200 may overlap at least one of the conductive layer 105 and the gate electrode 160 in a plan view. The above configuration is merely an embodiment, and the present invention is not limited to the above configuration.

### [Material of Each Layer of Semiconductor Device]

The substrate 100 may support each layer of the semiconductor device 10. For example, a rigid substrate having light transmittance such as a glass substrate, a quartz substrate, or a sapphire substrate can be used as the substrate 100. In addition, a rigid substrate having no light transmittance such as a silicon substrate can also be used as the substrate. Further, a flexible substrate having light transmittance such as a polyimide resin substrate, an acryl resin substrate, a siloxane resin substrate, or a fluororesin substrate can be used as the substrate. In order to improve the heat resistance of the substrate 100, impurities may be introduced into the resin substrate. A substrate in which a silicon oxide film or a silicon nitride film is formed on the above-described rigid substrate or flexible substrate can also be used as the substrate 100.

The conductive layer 105 may reflect or absorb external light.

Since the conductive layer 105 has an area larger than the channel region CH of the oxide semiconductor layer 140 as described above, external light incident on the channel region CH can be shielded. For example, aluminum (Al), copper (Cu), titanium (Ti), molybdenum (Mo), or tungsten (W), or an alloy or a compound thereof can be used as the conductive layer 105. If no conductivity is required, a resin layer composed of a black plastic or the like may be used instead of the conductive layer 105. The conductive layer 105 may have a single-layer structure or stacked structure.

The insulating layers 110, 120, 170, and 180 have a role of preventing impurity diffusion into the oxide semiconductor layer 140. The insulating layers 110, 120, 170, and 180 may have a single-layer structure or stacked structure. For example, silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), and aluminum nitride (AlNₓ) can be used as the insulating layers 110, 120, 170, and 180. In this case, silicon oxynitride (SiOₓN_{y}) and aluminum oxynitride (AlOₓN_{y}) are a silicon compound and an aluminum compound containing nitrogen (N) in a smaller proportion (x>y) than oxygen (O), respectively. In addition, silicon nitride oxide (SiNₓO_{y}) and aluminum nitride oxide (AlNₓO_{y}) are a silicon compound and an aluminum compound containing a smaller proportion (x>y) of oxygen than nitrogen. In the present embodiment, silicon nitride (SiNₓ) is used as the insulating layers 110 and 180, and silicon oxide (SiOₓ) is used as the insulating layers 120 and 170.

A metal oxide containing aluminum as a main component is used as the metal oxide layer 130. For example, an inorganic insulating layer such as aluminum oxide (AlOₓ), aluminum oxynitride (AlOₓN_{y}), aluminum nitride oxide (AlNₓO_{y}), or aluminum nitride (AlNₓ) is used as the metal oxide layer 130. The “metal oxide layer containing aluminum as a main component” means that the proportion of aluminum contained in the metal oxide layer 130 is 1% or more of the total amount of the metal oxide layer 130. The proportion of aluminum contained in the metal oxide layer 130 may be 5% or more and 70% or less, 10% or more and 60% or less, or 30% or more and 50% or less of the total amount of the metal oxide layer 130. The above proportion may be a mass ratio or a weight ratio.

In the present embodiment, the oxide semiconductor layer 140 has a polycrystalline structure. That is, the oxide semiconductor layer 140 of the present embodiment is composed of an oxide semiconductor formed using a Poly-OS technique. The Poly-OS technique refers to a technique of forming an oxide semiconductor layer with polycrystalline structure. A metal oxide with semiconductor characteristics can be used as the oxide semiconductor layer 140. For example, an oxide semiconductor containing two or more metals including indium (In) is used as the oxide semiconductor layer 140. The proportion of indium in the entire oxide semiconductor layer 140 is 50% or more. Gallium (Ga), zinc (Zn), aluminum (Al), hafnium (Hf), yttrium (Y), zirconia (Zr), and lanthanoids are used as the oxide semiconductor layer 140 in addition to indium. Elements other than those described above may be used as the oxide semiconductor layer 140.

Since the proportion of indium is 50% or more in the oxide semiconductor layer 140 of the present embodiment, oxygen vacancies are likely to be formed. On the other hand, oxygen vacancies are less likely to be formed in an oxide semiconductor with crystallinity than in an amorphous oxide semiconductor. Therefore, the oxide semiconductor layer 140 has an advantage that oxygen vacancies are hardly formed even though the proportion of indium is 50% or more.

The gate insulating layer 150 includes an insulating oxide. Specifically, silicon oxide (SiOₓ), silicon oxynitride (SiOₓN_{y}), aluminum oxide (AlOₓ), aluminum oxynitride (AlOₓN_{y}), or the like can be used as the gate insulating layer 150. The gate insulating layer 150 preferably has a composition close to the stoichiometric ratio. In addition, the gate insulating layer 150 is preferably less defective. For example, an oxide in which defects are not observed when evaluated by an electron-spin resonance method (ESR) may be used as the gate insulating layer 150.

The gate electrode 160, the source electrode 201, and the drain electrode 203 have conductivity. For example, copper (Cu), aluminum (Al), titanium (Ti), chromium (Cr), cobalt (Co), nickel (Ni), molybdenum (Mo), hafnium (Hf), tantalum (Ta), tungsten (W), or bismuth (Bi), or an alloy or a compound thereof can be used as each of the gate electrode 160, the source electrode 201, and the drain electrode 203. Each of the gate electrode 160, the source electrode 201, and the drain electrode 203 may have a single-layer structure or stacked structure.

### [Configuration of Oxide Semiconductor Layer]

The oxide semiconductor layer 140 is divided into the source region S, the drain region D, and the channel region CH. The channel region CH is a region positioned vertically below the gate electrode 160 of the oxide semiconductor layer 140 and in contact with the gate insulating layer 150. The source region S is a region of the oxide semiconductor layer 140 in contact with the insulating layer 170 and closer to the source electrode 201 than the channel region CH. The drain region D is a region of the oxide semiconductor layer 140 in contact with the insulating layer 170 and closer to the drain electrode 203 than the channel region CH. The source region S and the drain region D are formed by reducing resistance of part of the pattern composed of the oxide semiconductor layer. In other words, the channel region CH and the source region S and the drain region D are contiguous with each other in a first direction (direction D1) shown in FIG. 2.

The oxide semiconductor layer 140 in the channel region CH has physical properties as a semiconductor. The oxide semiconductor layer 140 in the source region S and the drain region D has physical properties as a conductor. That is, the source region S and the drain region D may be referred to as a region with a lower resistance than the channel region CH. In other words, the electrical conductivity of the source region S and the drain region D is greater than the electrical conductivity of the channel region CH. The source electrode 201 and the drain electrode 203 are respectively in contact with the source region S and the drain region D and electrically connected to the oxide semiconductor layer 140. The oxide semiconductor layer 140 may have a single-layer structure or stacked structure.

Part of the source region S and the drain region D in the semiconductor device 10 of the present embodiment overlaps the gate electrode 160, as shown in FIG. 1. Specifically, an end portion of the source region S closer to the channel region CH and the end portion of the drain region D closer to the channel region CH overlap a gate electrode 160. In other words, the end portion of the source region S closer to the channel region CH and the end portion of the drain region D closer to the channel region CH are respectively in contact with the gate insulating layer 150. That is, the source region S and the drain region D are in contact with both the gate insulating layer 150 and the insulating layer 170. In this case, a region where the source region S (or the drain region D) and the gate electrode 160 overlap is referred to as a “overlapping region OL”. A width of the overlapping region OL in the first direction is represented by ΔL/2 as shown in FIG. 1.

The semiconductor device 10 of the present embodiment has a symmetrical structure in the first direction (direction D1), and part of the source region S and drain region D overlap the gate wiring 160, respectively. Therefore, an end portion of the channel region CH in the first direction does not coincide with an end portion of the gate electrode 160. Specifically, the end portion of the channel region CH in contact with the source region S and the end portion of the channel region CH in contact with the drain region D are respectively positioned directly below the gate electrode 160. That is, the width of the channel region CH is narrower than the width of the gate electrode 160 in the first direction. This means that a designed channel length (hereinafter referred to as “design channel length”) is narrower than the design value by the amount of the presence of the overlapping region OL.

Generally, the design channel length of the top-gate transistor is determined by a width of the gate electrode overlapping the semiconductor layer. That is, in the case of the semiconductor device 10 of the present embodiment, the width of the gate electrode 160 in the first direction corresponds to the design channel length. However, the width of the channel region CH is narrower than the width of the gate electrode 160, as shown in FIG. 1. That is, an effective channel length corresponding to the width of the channel region CH is shorter than the design channel length corresponding to the width of the gate electrode 160. Specifically, a relationship of Leff=Lg−ΔL is established between the design channel length (Lg) and the effective channel length (Leff).

In the present embodiment, hydrogen diffusion from the insulating layers 170 and 180 to the oxide semiconductor layer 140 is utilized for forming the source region S and the drain region D. In this case, the overlapping region OL is formed because, structurally, hydrogen also diffuses into the oxide semiconductor layer 140 directly below the gate electrode 160. The overlapping region OL is a region formed by hydrogen entering the oxide semiconductor layer 140 positioned directly below the gate electrode 160. However, in the present embodiment, it is possible to suppress the range where the overlapping region OL is formed by reducing the amount of hydrogen diffusing directly below the gate electrode 160. Specifically, the semiconductor device 10 of the present embodiment is controlled so that the width (ΔL/2) of the overlapping region OL is 1 μm or less.

The width of the overlapping region OL is 1 μm or less means that the effective channel length of at least 2 μm can be ensured, for example, even if the design channel length is 4 μm. According to the present embodiment, the design channel length of the semiconductor device 10 (a width of the gate wiring in the first direction) can be set to 4 μm or less (preferably 3 μm or less). However, in order to ensure an effective channel length of at least 1 μm or more, the design channel length of the semiconductor device 10 is preferably larger than twice the width of the overlapping region OL (2×ΔL/2=ΔL) by 1 μm or more.

Since the gate insulating layer 150 has the same pattern shape as the gate electrode 160 in the semiconductor device 10 of the present embodiment as described above, part of the oxide semiconductor layer 140 is in contact with the insulating layer 170. Therefore, the semiconductor device 10 is structured such that part of the source region S and the drain region D extends below the gate electrode 160 due to the influence of hydrogen diffused from the insulating layers 170 and 180. However, according to the present embodiment, the width of the overlapping region OL where the source region S and the drain region D and the gate electrode 160 overlap can be suppressed to 1 μm or less, so that the deviation between the design channel length and the effective channel length can be suppressed.

### [Method for Manufacturing Semiconductor Device]

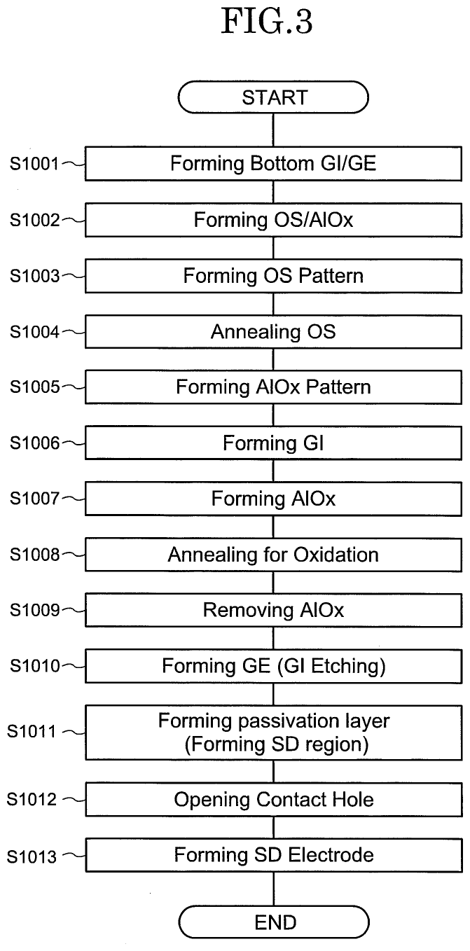

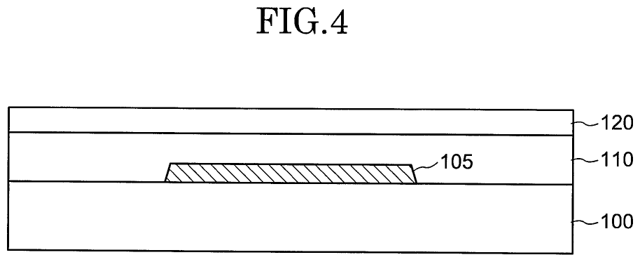

A method for manufacturing the semiconductor device 10 according to an embodiment of the present invention will be described with reference to FIG. 3 to FIG. 12. FIG. 3 is a sequence diagram showing the method for manufacturing the semiconductor device 10 according to an embodiment of the present invention. FIG. 4 to FIG. 12 are cross-sectional views showing the method for manufacturing the semiconductor device 10 according to an embodiment of the present invention.

The conductive layer 105 is formed as a light-shielding layer on the substrate 100, and the insulating layers 110 and 120 are formed on the conductive layer 105 (step S1001 in FIG. 4), as shown in FIG. 3 and FIG. 4. For example, silicon nitride is formed as the insulating layer 110. For example, silicon oxide is formed as the insulating layer 120. The insulating layers 110 and 120 are formed by a CVD (Chemical Vapor Deposition) method. Performing deposition on the substrate by a method such as a sputtering method or the CVD method is expressed as “forming a thin film” in the present specification, but is used in the same sense as the expression “depositing a thin film”.

The use of silicon nitride as the insulating layer 110 allows the insulating layer 110 to block impurities that diffuse, for example, from the substrate 100 toward the oxide semiconductor layer 140. The silicon oxide used as insulating layer 120 is silicon oxide having physical properties of releasing oxygen by a heat treatment.

The deposition temperature is set to 350° C. when forming the insulating layers 110 and 120 in the present embodiment. In particular, the oxygen content in the insulating layer 120 (that is, the silicon oxide layer) can be increased by setting the deposition temperature to a relatively low temperature. Increasing the amount of oxygen contained in the insulating layer 120 makes it possible to reduce the amount of hydrogen diffused into the oxide semiconductor layer 140 as will be described later. The deposition temperatures of the insulating layers 110 and 120 may be set to 250° C. or higher and 500° C. or lower (preferably 300° C. or higher and 450° C. or lower, and more preferably 325° C. or higher and 400° C. or lower).

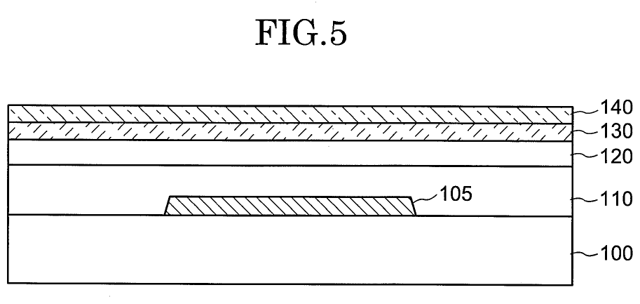

Next, the metal oxide layer 130 and the oxide semiconductor layer 140 are formed on the insulating layer 120 (step S1002 in FIG. 3) as shown in FIG. 3 and FIG. 5. The metal oxide layer 130 and the oxide semiconductor layer 140 are formed by a sputtering method in the present embodiment. In particular, the oxide semiconductor layer 140 is formed by sputtering using the target formed of the oxide semiconductor with crystallinity.

For example, a thickness of the metal oxide layer 130 is 1 nm or more and 10 nm or less, 1 nm or more and 4 nm or less, or 1 nm or more and 3 nm or less. In the present embodiment, the thickness of the metal oxide layer 130 is defined as 3 nm. An oxide containing aluminum as a main component (specifically, aluminum oxide) is used as the metal oxide layer 130. Aluminum oxide has a high barrier property against gas.

In the present embodiment, the aluminum oxide used as the metal oxide layer 130 blocks hydrogen and oxygen released from the insulating layer 120 and suppresses the released hydrogen and oxygen from reaching the oxide semiconductor layer 140.

Since the proportion of indium is 50% or more in the oxide semiconductor layer 140 of the present embodiment as described above, the semiconductor device 10 with high mobility can be realized, but oxygen is easily reduced and oxygen vacancies are easily formed in the layer. Therefore, it is preferable to block hydrogen released from the insulating layer 120 by the metal oxide layer 130 in order to suppress reduction of the oxide semiconductor layer 140.

In addition, after the oxide semiconductor layer 140 is formed, more oxygen vacancies are formed on the upper layer side of the oxide semiconductor layer 140 than on the lower layer side in various manufacturing processes (patterning process or etching process). That is, the oxygen vacancies in the oxide semiconductor layer 140 are non-uniformly distributed in the thickness direction. In this case, if the amount of oxygen sufficient to repair the oxygen vacancies formed on the upper layer side of the oxide semiconductor layer 140 is supplied, oxygen will be excessively supplied to the lower layer side of the oxide semiconductor layer 140. As a result, the excessively supplied oxygen forms a defect level different from the oxygen vacancies, which may lead to a phenomenon such as characteristic fluctuation or a decrease in field-effect mobility in a reliability test. Therefore, blocking the oxygen released from the insulating layer 120 by the metal oxide layer 130 is also preferable to suppress excessive oxygen supply to the lower layer side of the oxide semiconductor layer 140.

For example, a thickness of the oxide semiconductor layer 140 is 10 nm or more and 100 nm or less, 15 nm or more and 70 nm or less, or 15 nm or more and 40 nm or less. The oxide semiconductor layer 140 before the heat treatment (OS annealing) described later is amorphous.

The oxide semiconductor layer 140 is preferably amorphous (a state in which the oxide semiconductor has few crystalline components) from the formation by the sputtering method to before OS annealing when the oxide semiconductor layer 140 is crystallized by OS annealing described later. That is, the conditions for forming the oxide semiconductor layer 140 are preferably such that the oxide semiconductor layer 140 immediately after formation is not crystallized as much as possible. For example, in the case where the oxide semiconductor layer 140 is formed by the sputtering method, it is desirable to form the oxide semiconductor layer 140 while controlling the temperature of an object to be formed (including the substrate 100 and the structure formed thereon). In addition, the object to be temperature controlled is the object to be formed, but since the structure formed on the substrate 100 is very thin, it may be considered that the temperature of the substrate 100 is substantially controlled. Therefore, the object to be formed may be simply referred to as a “substrate” in the following explanation.

When a substrate is subjected to thin film formation (deposition) by the sputtering method, ions generated in the plasma and atoms recoiled by the sputtering target collide with the object to be formed (specifically, the structure formed on the substrate 100), so that the temperature of the substrate increases in the process of forming the thin film. When the temperature of the substrate is increased in the process of forming the thin film, microcrystals are contained in the oxide semiconductor layer 140 in a state immediately after the formation, and crystallization due to subsequent OS annealing is inhibited.

In order to control the temperature of the substrate in forming the oxide semiconductor layer 140 (that is, the deposition temperature), for example, the thin film may be formed while the substrate is cooled. For example, the substrate can be cooled from the other side of the surface to be formed so that the deposition temperature may be 100° C. or lower, 70° C. or lower, 50° C. or lower, or 30° C. or lower. In particular, the deposition temperature of the oxide semiconductor layer 140 is preferably 50° C. or lower. In the present embodiment, the oxide semiconductor layer 140 is formed at a deposition temperature of 50° C. or lower, and OS annealing, which will be described later, is performed at a heating temperature of 400° C. or higher. It is preferable that the difference between the temperature when forming the oxide semiconductor layer 140 and the temperature when performing OS annealing on the oxide semiconductor layer 140 is 350° C. or higher as described above. Forming the oxide semiconductor layer 140 while the substrate is cooled makes it possible to obtain the oxide semiconductor layer 140 with few crystalline components in a state immediately after the formation.

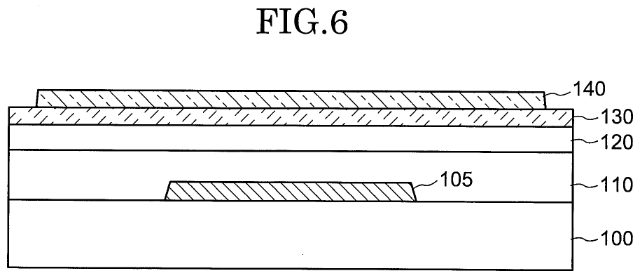

Next, a pattern (OS pattern) composed of the oxide semiconductor layer 140 is formed (step S1003 in FIG. 3) as shown in FIG. 3 and FIG. 6. Although not shown, a resist mask is formed on the oxide semiconductor layer 140, and the oxide semiconductor layer 140 is etched using the resist mask patterned by photolithography. Etching of the oxide semiconductor layer 140 may be performed by wet etching or dry etching. For example, an acidic etchant can be used in the wet etching. Specifically, oxalic acid or hydrofluoric acid can be used as the etchant.

A heat treatment (OS annealing) is performed on the oxide semiconductor layer 140 (step S1004 in FIG. 4) after the pattern of the oxide semiconductor layer 140 is formed. In OS annealing, the oxide semiconductor layer 140 in the amorphous state is crystallized by performing a heat treatment on the oxide semiconductor layer 140 in an atmosphere at a temperature of 250° C. or higher and 500° C. or lower (preferably 300° C. or higher and 500° C. or lower, and more preferably 350° C. or higher and 450° C. or lower). The heating atmosphere is not limited to the atmospheric atmosphere, but is preferably an oxidizing atmosphere (an atmosphere containing oxygen). More preferably, the oxidizing atmosphere is a wet atmosphere (specifically, a wet atmospheric atmosphere). In addition, the treatment time of the heat treatment may be 15 minutes or more and 120 minutes or less, or 30 minutes or more and 60 minutes or less after reaching the predetermined temperature. In the present embodiment, the temperature of OS annealing is set at 350° C.

In the present embodiment, the substrate on which the patterned oxide semiconductor layer 140 is formed is charged into a heating furnace having a heating medium (for example, a support plate) maintained at a set temperature (250° C. or higher and 500° C. or lower, in the present embodiment, 350° C.) in advance. The support plate as the heating medium has the role of supporting the substrate and heating the substrate and the film formed on the substrate (including the oxide semiconductor layer 140). The oxide semiconductor layer 140 is rapidly heated by installing the substrate on which the oxide semiconductor layer 140 is formed on the support plate. It is desirable to keep the temperature drop of the support plate within 15%, within 10%, or within 5% of the set temperature when installing the substrate in the heating furnace. That is, it is preferable to control the temperature of the support plate so that the oxide semiconductor layer 140 reaches the set temperature in as short a time as possible.

Although an example in which OS annealing is performed after forming OS pattern has been described in the present embodiment, the present invention is not limited to this example, and OS annealing may be performed on the oxide semiconductor layer 140 before forming OS pattern. In this case, since the OS pattern is formed by etching the crystallized oxide semiconductor layer 140, the etching process is preferably dry etching.

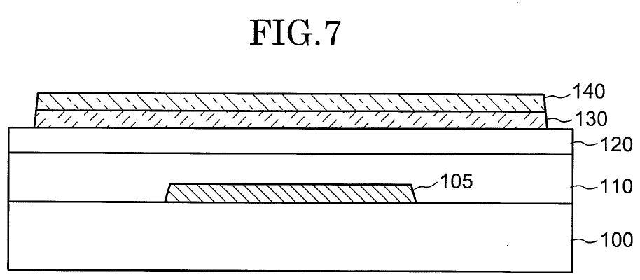

Next, a pattern composed of the metal oxide layer 130 (AlOₓ pattern) is formed (step S1005 in FIG. 3), as shown in FIG. 3 and FIG. 7. The crystallized the oxide semiconductor layer 140 has etching resistance to hydrofluoric acid. Therefore, the metal oxide layer 130 of the present embodiment is etched using the oxide semiconductor layer 140 patterned in the above-described process as a mask. Etching of the metal oxide layer 130 may be performed by wet etching or dry etching. For example, dilute hydrofluoric acid (DHF) is used in wet etching. Etching the metal oxide layer 130 using the oxide semiconductor layer 140 as a mask makes it possible to omit the photolithography step. Since the metal oxide layer 130 is etched using the oxide semiconductor layer 140 as a mask, the metal oxide layer 130 and the oxide semiconductor layer 140 have the same pattern shape.

Although an example in which the OS pattern is formed and then the AlOₓ pattern is formed using the OS pattern as a mask has been shown in the present embodiment, the OS pattern and the AlOₓ pattern may be collectively formed. In this case, the oxide semiconductor layer 140 and the metal oxide layer 130 may be simultaneously etched using the same resist mask in step S1003 in FIG. 3.

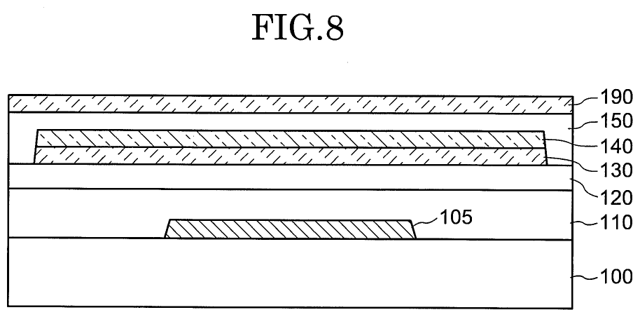

Next, the gate insulating layer 150 is formed (step S1006 in FIG. 3), as shown in FIG. 3 and FIG. 8. For example, a silicon oxide layer is formed as the gate insulating layer 150. The gate insulating layer 150 is formed by the CVD method. It is desirable to form an insulating layer with as few defects as possible as the gate insulating layer 150. The deposition temperature of the gate insulating layer 150 is 350° C. in the present embodiment. For example, a thickness of the gate insulating layer 150 is 50 nm or more and 300 nm or less, 60 nm or more and 200 nm or less, or 70 nm or more and 150 nm or less.

Next, in the present embodiment, after the gate insulating layer 150 is formed, a metal oxide layer 190 is formed on the gate insulating layer 150 (step S1007 in FIG. 3). The metal oxide layer 190 is formed by the sputtering method. By using the sputtering method for depositing the metal oxide layer 190, oxygen is implanted into the gate insulating layer 150 when forming the metal oxide layer 190. Therefore, the gate insulating layer 150 after forming the metal oxide layer 190 contains a large amount of oxygen.

For example, a thickness of the metal oxide layer 190 is 5 nm or more and 100 nm or less, 5 nm or more and 50 nm or less, 5 nm or more and 30 nm or less, or 7 nm or more and 15 nm or less. In the present embodiment, aluminum oxide is used as the metal oxide layer 190. Since the aluminum oxide has a high barrier property against gas as described above, it is possible to suppress the oxygen implanted into the gate insulating layer 150 from diffusing upward during the heat treatment described later.

In the case where the metal oxide layer 190 is formed by the sputtering method, a process gas used in sputtering remains in the film of the metal oxide layer 190. For example, in the case where Ar is used as the process gas for sputtering, Ar may remain in the film of the metal oxide layer 190. The remaining Ar can be detected by SIMS (Secondary lon Mass Spectrometry) or the like with respect to the metal oxide layer 190.

Next, a heat treatment (oxidation annealing) for supplying oxygen to the oxide semiconductor layer 140 is performed (step S1008 in FIG. 3) in a state where the metal oxide layer 190 is formed on the gate insulating layer 150. In other words, a heat treatment (oxidation annealing) is performed on the patterned metal oxide layer 130 and the oxide semiconductor layer 140. Oxygen vacancies may occur on the upper surface 141 and the side surface 143 of the oxide semiconductor layer 140 during the process from the formation of the oxide semiconductor layer 140 to the formation of the gate insulating layer 150 on the oxide semiconductor layer 140. Oxidation annealing supplies oxygen released from the insulating layer 120 and the gate insulating layer 150 to the oxide semiconductor layer 140 and repairs the oxygen vacancies. The oxidation annealing may be performed at a temperature of 250° C. or higher and 500° C. or lower (preferably 300° C. or higher and 500° C. or lower, and more preferably 350° C. or higher and 450° C. or lower). In the present embodiment, the oxidation annealing is performed at a temperature of 350° C.

Since the oxygen released from the insulating layer 120 by the oxidation annealing is blocked by the metal oxide layer 130, oxygen is not easily supplied to the lower surface 142 of the oxide semiconductor layer 140. The oxygen released from the insulating layer 120 diffuses from a region where the metal oxide layer 130 is not formed to the gate insulating layer 150 and reaches the oxide semiconductor layer 140 via the gate insulating layer 150. As a result, the oxygen released from the insulating layer 120 is less likely to be supplied to the lower surface 142 of the oxide semiconductor layer 140, and is mainly supplied to the side surface 143 and the upper surface 141 of the oxide semiconductor layer 140. Further, the oxygen released from the gate insulating layer 150 is supplied to the upper surface 141 and the side surface 143 of the oxide semiconductor layer 140 by oxidation annealing. Hydrogen may be released from the insulating layer 110 due to the above oxidation annealing. However, the hydrogen is captured by the oxygen contained in the insulating layer 120 or blocked by the metal oxide layer 130 before reaching the oxide semiconductor layer 140.

As described above, it is possible to supply oxygen to the upper surface 141 and the side surface 143 of the oxide semiconductor layer 140 with a relatively large amount of oxygen vacancies by the oxidation annealing while suppressing the supply of oxygen to the lower surface 142 of the oxide semiconductor layer 140 with a small amount of oxygen vacancies. Similarly, since the upward diffusion of the oxygen implanted in the gate insulating layer 150 is blocked by the metal oxide layer 190 during the oxidation annealing, the oxygen is suppressed from being released into the atmosphere. Therefore, oxygen can be efficiently supplied to the oxide semiconductor layer 140 during the oxidation annealing.

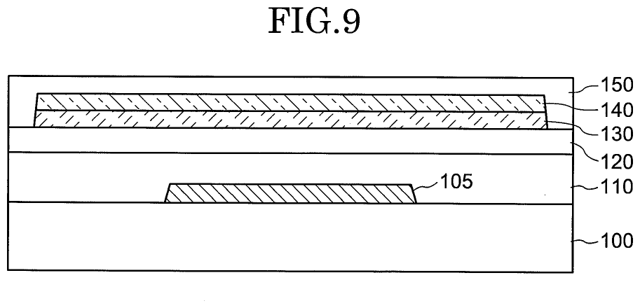

Next, the metal oxide layer 190 is etched and removed (step S1009 in FIG. 3) after the oxidation annealing, as shown in FIG. 3 and FIG. 9. The etching of the metal oxide layer 190 may be wet etching or dry etching. For example, dilute hydrofluoric acid (DHF) is used as an etchant in wet etching. The entire metal oxide layer 190 is removed by the etching process of step S1009.

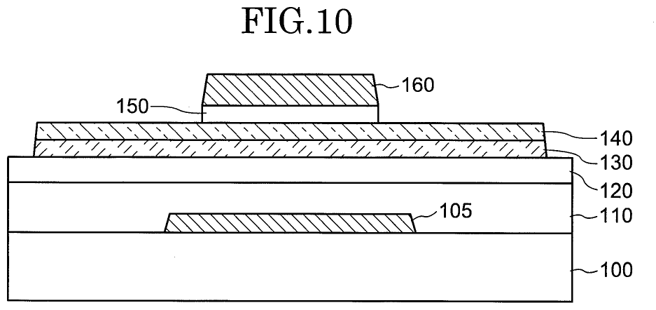

Next, the gate insulating layer 150 is etched after the gate electrode 160 is formed on the gate insulating layer 150 (step S1010 in FIG. 3), as shown in FIG. 3 and FIG. 10. The gate electrode 160 is formed by patterning the metal layer formed by the sputtering method or an atomic layer deposition method, and then dry etching. The gate insulating layer 150 is etched by further dry etching after forming the gate electrode 160. That is, the gate insulating layer 150 is etched using the gate electrode 160 as a mask. The patterned gate insulating layer 150 and the gate electrode 160 are formed by etching the metal layer and the gate insulating layer 150 at once in the present embodiment as described above.

In the present embodiment, part of the oxide semiconductor layer 140 (a region which becomes the source region S and the drain region D, which will be described later) is exposed by etching the gate insulating layer 150 using the gate electrode 160 as a mask. In addition, since the etching is performed using the gate electrode 160 as a mask, the gate insulating layer 150 and the gate electrode 160 have the same pattern shape.

In the case where the gate insulating layer 150 is etched until the oxide semiconductor layer 140 is exposed, not only the upper surface 141 of the oxide semiconductor layer 140 but also the side surface 143 of the oxide semiconductor layer 140 is exposed, as shown in FIG. 10. Further, the side surface of the metal oxide layer 130 and an upper surface of the insulating layer 120 are also exposed. In this case, since the insulating layer 120 is composed of a silicon oxide layer in the same manner as the gate insulating layer 150, it is desirable to stop the etching process immediately when the upper surface 141 of the oxide semiconductor layer 140 is exposed without making the etching time excessively long.

If the etching time is excessively long, the insulating layer 120 may be deeply etched, causing a large step between an end portion of the metal oxide layer 130 and the upper surface of the insulating layer 120. Such a step may adversely affect the electrical characteristics of the semiconductor device 10 (for example, an increase in leakage current and the like). Conversely, if the etching time is insufficient, the gate insulating layer 150 may remain on the oxide semiconductor layer 140, adversely affecting the electrical characteristics of the semiconductor device 10 (for example, a shift of the threshold voltage in the negative direction and the like). Therefore, in the present embodiment, a slight over etching is performed (for example, the above-described etching time is extended by 10%) with respect to the etching time required for the upper surface 141 of the oxide semiconductor layer 140 to be exposed, thereby preventing deterioration of electrical characteristics.

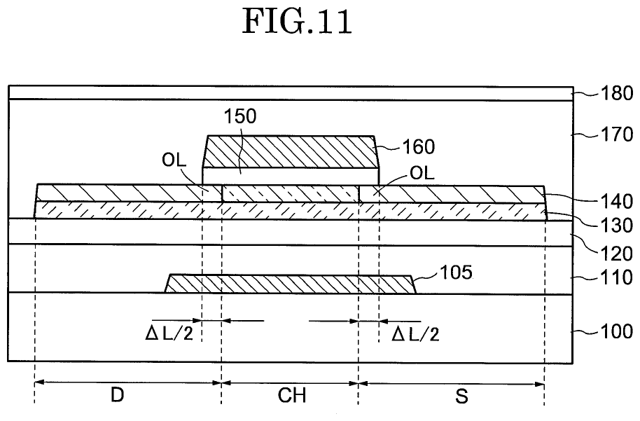

Next, the insulating layers 170 and 180 are formed as a passivation layer on the gate insulating layer 150 and the gate wiring 160 (step S1011 in FIG. 3) as shown in FIG. 3 and FIG. 11. The insulating layers 170 and 180 are formed by the CVD method. In the present embodiment, a silicon oxide layer is formed as the insulating layer 170, and a silicon nitride layer is formed as the insulating layer 180.

The deposition temperature of the insulating layers 170 and 180 is preferably set to 250° C. or higher and 500° C. or lower (preferably 300° C. or higher and 450° C. or lower, and more preferably 325° C. or higher and 400° C. or lower). In the present embodiment, the deposition temperature of the insulating layers 170 and 180 is set to 350° C. The thickness of the insulating layers 170 and 180 may be 50 nm or more and 500 nm or less. In the present embodiment, the thickness of the insulating layer 170 is 100 nm, and the thickness of the insulating layer 180 is 300 nm.

The insulating layers 170 and 180 function as the passivation layer (protective layer) to prevent gas and moisture from entering from the outside. The insulating layers 170 and 180 also have the role of insulating and separating the gate wiring 160 and the source/drain electrode 200 as discussed above. Further, in the present embodiment, the source region S and the drain region D are formed in the oxide semiconductor layer 140 by forming the insulating layers 170 and 180 (in particular, the insulating layer 180).

The insulating layer 180 of the present embodiment is composed of silicon nitride. Since ammonia is used as a source gas when forming the insulating layer 180 by the CVD method, the insulating layer 180 contains a large amount of hydrogen. Therefore, when forming the insulating layer 180 and after the formation of the insulating layer 180, hydrogen is diffused from the insulating layer 180 by heating the insulating layer 180. The diffused hydrogen reaches the oxide semiconductor layer 140 via the insulating layer 170. In this case, the oxygen contained in the region of the oxide semiconductor layer 140 in contact with the insulating layer 170 is reduced, and oxygen vacancies are formed. Hydrogen is trapped in the formed oxygen vacancies which forms donor levels. As a result, the resistance of part of the hydrogen-supplied oxide semiconductor layer 140 is reduced and functions as the source region S and the drain region D. On the other hand, the resistance of the oxide semiconductor layer 140 positioned directly below the gate wiring 160 is not reduced because hydrogen does not reach it and functions as the channel region CH.

Since the gate insulating layer 150 has the same pattern shape as the gate wiring 160 in the semiconductor device 10 of the present embodiment, the oxide semiconductor layer 140 exposed from the gate insulating layer 150 is in direct contact with the insulating layer 170. Therefore, the structure is such that hydrogen is diffused easily below the gate wiring 160 as compared with the structure in which the oxide semiconductor layer 140 is entirely covered with the gate insulating layer 150. Therefore, the resistance of a part of a region that should be the channel region CH is also reduced by the hydrogen diffused below the gate wiring 160 as shown in FIG. 11. That is, the source region S and the drain region D extend toward the channel region CH to form the overlapping region OL.

In the present embodiment, the width (ΔL) of the overlapping region OL in the first direction (channel length direction) can be suppressed to 1 μm or less as described above. The deviation between the design channel length and the effective channel length can be suppressed by suppressing the width of the overlapping region OL to 1 μm or less. As a result, stable electrical characteristics can be obtained in the semiconductor device 10 of the present embodiment even when the channel length is 4 μm or less.

The reason why the width (ΔL) of the overlapping region OL can be suppressed to 1 μm or less is that a large amount of oxygen is contained in the insulating layer 120 (in the present embodiment, the silicon oxide layer) arranged below the oxide semiconductor layer 140.

The insulating layer 120 containing a large amount of oxygen and the insulating layer 170 are in direct contact with each other around the oxide semiconductor layer 140 in a plan view. Therefore, a large amount of hydrogen diffused from the insulating layers 170 and 180 is captured by the insulating layer 120, and the amount of hydrogen diffused toward the oxide semiconductor layer 140 is suppressed. In this case, although the resistance of the source region S and the drain region D of the oxide semiconductor layer 140 are reduced sufficiently even if the amount of hydrogen to be diffused is small because they are in direct contact with the insulating layer 170, the amount of hydrogen to be diffused below the gate wiring 160 decreases. As a result, in the present embodiment, it is considered that the width of the overlapping region OL (that is, the diffusion length of hydrogen) is shortened.

For example, in order to increase the oxygen content of the insulating layer 120, it is preferable to set the deposition temperature of the insulating layer 120 to a relatively low temperature. Although the temperature is set to 350° C. in the present embodiment, the temperature may be within a range of 250° C. or higher 500° C. or lower (preferably 300° C. or higher 500° C. or lower, more preferably 350° C. or higher 450° C. or lower).

In addition, although the present embodiment includes the process of forming the metal oxide layer 130 on the insulating layer 120, this process also contributes to increasing the oxygen content of the insulating layer 120. Specifically, in the case where the metal oxide layer 130 is formed by the sputtering method, oxygen is implanted into the insulating layer 120. As a result, the total amount of oxygen in the insulating layer 120 can be increased because oxygen is further implanted into the insulating layer 120 in which the oxygen content is increased at the above-described deposition temperature.

As described above, the semiconductor device 10 of the present embodiment has a structure in which the oxide semiconductor layer 140 and the insulating layer 170 are in direct contact by processing the gate insulating layer 150 into the same pattern shape as the gate wiring 160. As a result, the resistance of part of the oxide semiconductor layer 140 can be made low by using the hydrogen diffusing from the insulating layers 170 and 180, and the source region S and the drain region D can be formed. In addition, since a large amount of oxygen is contained in the insulating layer 120 underlying the oxide semiconductor layer 140, the amount of hydrogen used for reducing the resistance of the oxide semiconductor layer 140 can be reduced. As a result, it is possible to suppress the hydrogen diffusion directly below the gate wiring 160 and shorten the width of the overlapping region OL.

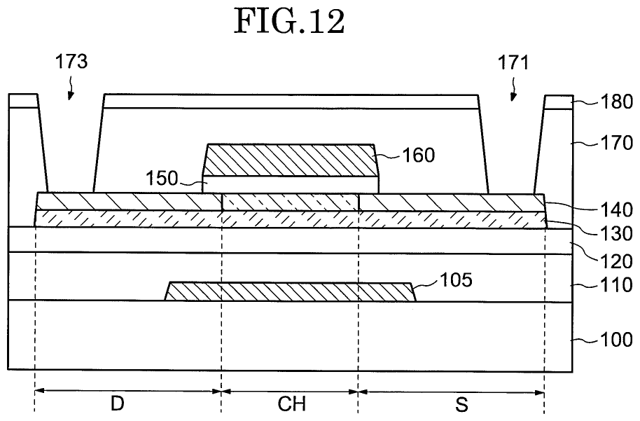

Next, the openings 171 and 173 are formed in the gate insulating layer 150 and the insulating layers 170 and 180 (step S1012 in FIG. 3), as shown in FIG. 3 and FIG. 12. The opening 171 exposes the oxide semiconductor layer 140 in the source region S. The opening 173 exposes the oxide semiconductor layer 140 in the drain region D. Forming the source/drain electrode 200 on the oxide semiconductor layer 140 and the insulating layer 180 exposed by the openings 171 and 173 (step S1013 in FIG. 3) completes the semiconductor device 10 shown in FIG. 1.

Electrical characteristics having a field-effect mobility of 30 cm²/Vs or more, 35 cm²/Vs or more, or 40 cm²/Vs or more can be obtained in a range where the channel length L of the channel region CH is 2 μm or more and 4 μm or less and the channel width of the channel region CH is 2 μm or more and 25 μm or less in the semiconductor device 10 formed by the manufacturing process of the present embodiment. The “field-effect mobility” in the present embodiment means the field-effect mobility in a saturated region of the semiconductor device 10, indicating the maximum value of the field-effect mobility in a region where a potential difference (Vd) between the source electrode and the drain electrode is greater than a value obtained by subtracting a threshold voltage (Vth) of the semiconductor device 10 from a voltage (Vg) supplied to gate electrode (Vg-Vth).

### Second Embodiment

In the present embodiment, a semiconductor device manufactured using a method different from that of the first embodiment will be described. A structure of the semiconductor device 10 of the present embodiment is the same as that of the semiconductor device 10 described in the first embodiment. The present embodiment will be described focusing on differences from the first embodiment.

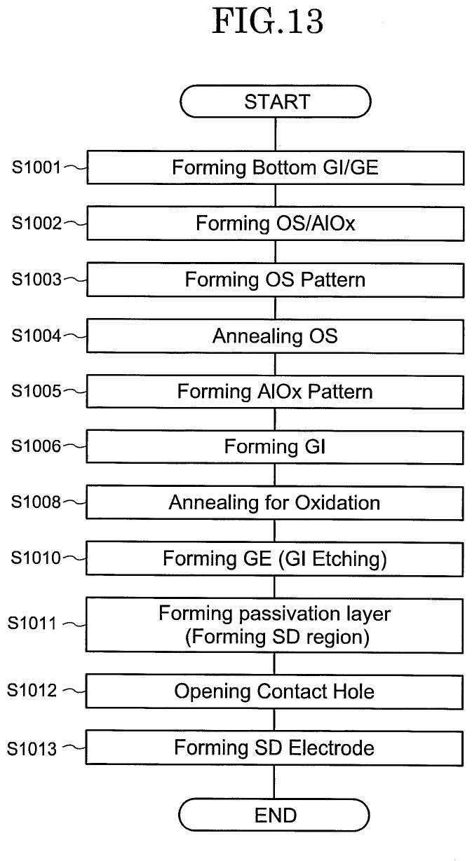

FIG. 13 is a sequence diagram showing a method for manufacturing the semiconductor device 10 according to an embodiment of the present invention. The two steps of step S1007 (Forming AlOₓ) and S1009 (Removing AlOₓ) shown in FIG. 3 are omitted in the present embodiment as shown in FIG. 13. That is, in the present embodiment, after the gate insulating layer 150 is formed, oxidative annealing is performed in that state. The oxygen released from the gate insulating layer 150 is supplied to the oxide semiconductor layer 140 by the oxidation annealing, and the oxygen vacancies contained in the oxide semiconductor layer 140 are repaired. Since the role of the metal oxide layer 130 in this case is the same as that of the first embodiment, the description thereof will be omitted.

Electrical characteristics having a mobility of 30 cm²/Vs or more, 35 cm²/Vs or more, or 40 cm²/Vs or more can be obtained in a range where the channel length L of the channel region CH is 2 μm or more and 4 μm or less and the channel width W of the channel region CH is 2 μm or more and 25 μm or less in the semiconductor device 10 formed by the manufacturing method of the present embodiment. The definition of the field-effect mobility in the present embodiment is the same as that in the first embodiment.

### Third Embodiment

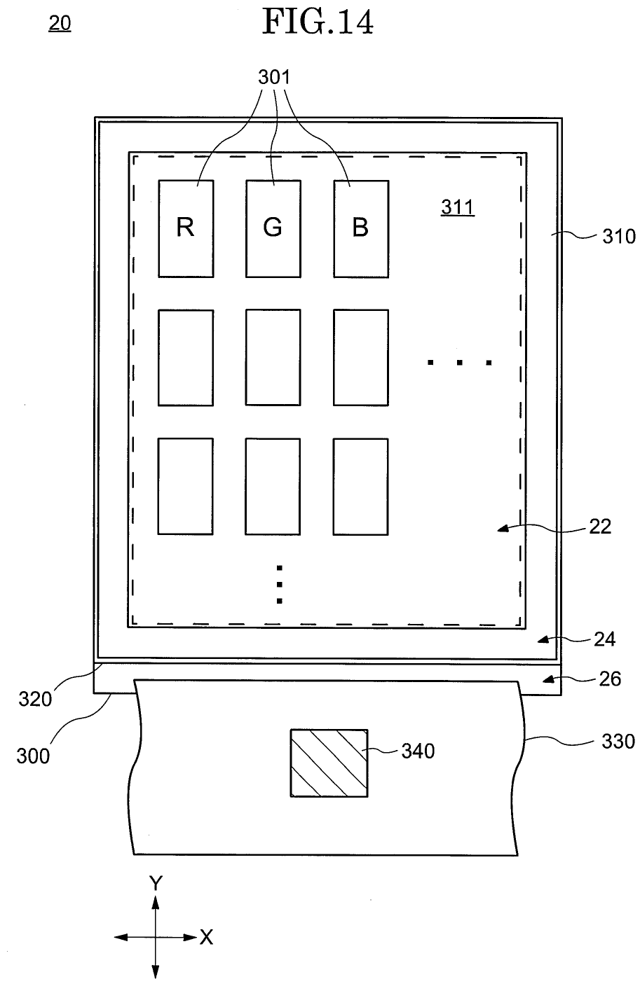

A display device using the semiconductor device according to an embodiment of the present invention will be described with reference to FIG. 14 to FIG. 18. A configuration in which each semiconductor device described in the first embodiment and the second embodiment is applied to a circuit of a liquid crystal display device circuit will be described in the embodiment described below.

### [Outline of Display Device]

FIG. 14 is a plan view showing an outline of a display device 20 according to an embodiment of the present invention. The display device 20 includes an array substrate 300, a sealing portion 310, a counter substrate 320, a flexible printed circuit substrate 330 (FPC 330), and an IC chip 340, as shown in FIG. 14. The array substrate 300 and the counter substrate 320 are bonded together by the sealing portion 310. A plurality of pixel circuits 301 is arranged in a matrix in a liquid crystal region 22 surrounded by the sealing portion 310. The liquid crystal region 22 is a region overlapping a liquid crystal element 311 described later in a plan view.

A seal region 24 where the sealing portion 310 is arranged is a region around the liquid crystal region 22. The FPC 330 is arranged in a terminal region 26. The terminal region 26 is a region of the array substrate 300 exposed from the counter substrate 320 and is arranged on the outside of the seal region 24. The outside of the seal region 24 means the outside of the region where the sealing portion 310 is arranged and the region surrounded by the sealing portion 310. The IC chip 340 is arranged on the FPC 330. The IC chip 340 supplies a signal for driving the pixel circuit 301.

### [Circuit Configuration of Display Device]

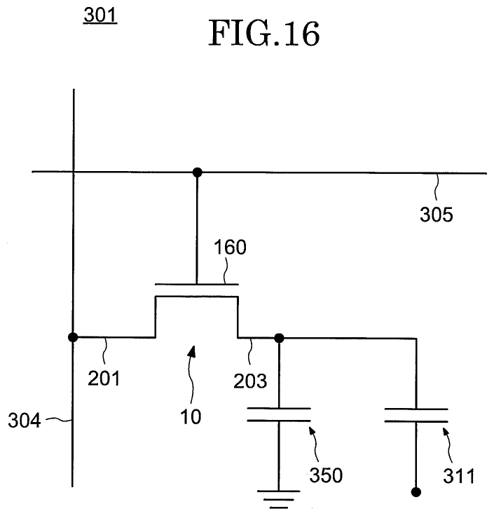

FIG. 16 is a block diagram showing a circuit configuration of the display device 20 according to an embodiment of the present invention. A source driver circuit 302 is arranged at a position adjacent to the liquid crystal region 22 on which the pixel circuit 301 is arranged in the direction Y (column direction), as shown in FIG. 16. In addition, a gate driver circuit 303 is arranged at a position adjacent to the liquid crystal region 22 in the direction X (row direction). The source driver circuit 302 and the gate driver circuit 303 are arranged in the seal region 24. However, the region where the source driver circuit 302 and the gate driver circuit 303 are arranged is not limited to the seal region 24, and any region may be used as long as it is outside the region where the pixel circuit 301 is arranged.

A source wiring 304 extends from the source driver circuit 302 in the direction Y and is connected to the plurality of pixel circuits 301 arranged in the direction Y. A gate wiring 305 extends from the gate driver circuit 303 in the direction X and is connected to the plurality of pixel circuits 301 arranged in the direction X.

A terminal portion 306 is arranged in the terminal region 26. The terminal portion 306 and the source driver circuit 302 are connected by a connecting wiring 307. Similarly, the terminal portion 306 and the gate driver circuit 303 are connected by a connecting wiring 308. The FPC 330 is connected to the terminal portion 306, so that an external device and the display device 20 are connected via the FPC 330. Each pixel circuit 301 arranged in the display device 20 is driven by a signal from the external device input via the FPC 330.

The semiconductor device 10 described in the first embodiment and the second embodiment is used as a transistor included in the pixel circuit 301, the source driver circuit 302, and the gate driver circuit 303.

### [Pixel Circuit of Display Device]

FIG. 16 is a circuit diagram showing the pixel circuit 301 of the display device 20 according to an embodiment of the present invention. The pixel circuit 301 includes elements such as the semiconductor device 10, a storage capacitor 350, and the liquid crystal element 311, as shown in FIG. 16.

The semiconductor device 10 includes the gate wiring 160, the source electrode 201, and the drain electrode 203. The gate wiring 160 is connected to the gate wiring 305. The source electrode 201 is connected to the source wiring 304. The drain electrode 203 is connected to the storage capacitor 350 and the liquid crystal element 311. The roles of the source electrode 201 and the drain electrode 203 may be switched depending on the relationship between the voltage supplied to the source wiring 304 and the voltage stored in the storage capacitor 350. That is, the source electrode 201 may function as a drain electrode, and the drain electrode 203 may function as a source electrode.

### [Cross-Sectional Structure of Display Device]

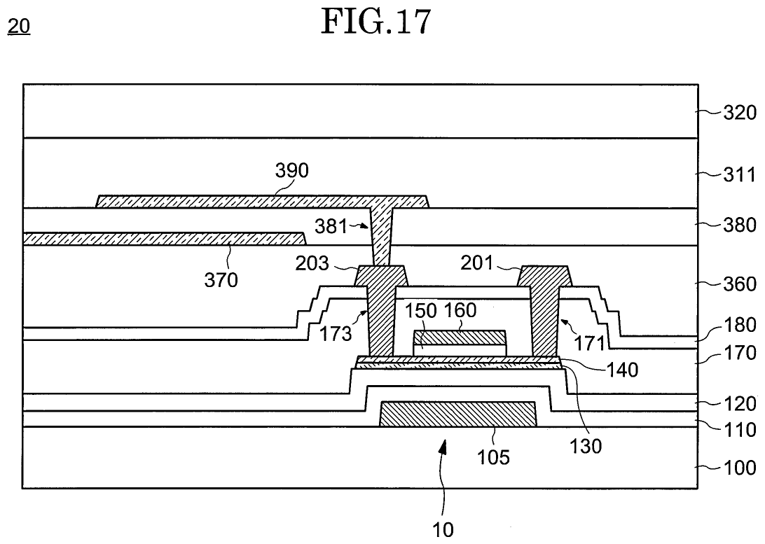

FIG. 17 is a cross-sectional view showing an outline of the display device 20 according to an embodiment of the present invention. The display device 20 is a display device in which the semiconductor device 10 is used as shown in FIG. 17. Although a configuration in which the semiconductor device 10 is used for the pixel circuit 301 is exemplified in the present embodiment, the semiconductor device 10 may be used for a peripheral circuit including the source driver circuit 302 and the gate driver circuit 303. Since the configuration of the semiconductor device 10 is the same as that of the semiconductor device 10 shown in FIG. 1 in the following description, detailed description thereof will be omitted.

An insulating layer 360 is arranged on the source electrode 201 and the drain electrode 203. A common electrode 370 arranged in common to the plurality of pixels is arranged on the insulating layer 360. An insulating layer 380 is arranged on the common electrode 370. An opening 381 is arranged in the insulating layers 360 and 380. A pixel electrode 390 is arranged on the insulating layer 380 and inside the opening 381. The pixel electrode 390 is connected to the drain electrode 203.

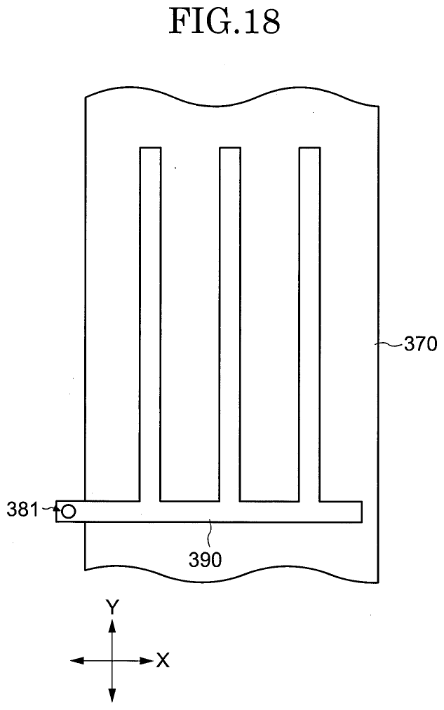

FIG. 18 is a plan view of the pixel electrode 390 and the common electrode 370 of the display device 20 according to an embodiment of the present invention. The common electrode 370 is composed of a flat-shaped conductive layer as shown in FIG. 18. The pixel electrode 390 is composed of a comb-shaped conductive layer in which a part extending in the direction X and a part extending in the direction Y are combined. The part extending in the direction Y is composed of a plurality of linear electrodes, and is connected to the part extending in the direction X.

The common electrode 370 includes an overlapping region overlapping the pixel electrode 390 and a non-overlapping region not overlapping the pixel electrode 390. An electric field in the transverse direction is formed from the pixel electrode 390 in the overlapping region towards the common electrode 370 in the non-overlapping region when a voltage is applied between the pixel electrode 390 and the common electrode 370. The gradation of the pixel is determined by operating the liquid crystal molecules included in the liquid crystal element 311 due to the electric field in the transverse direction.

### Fourth Embodiment

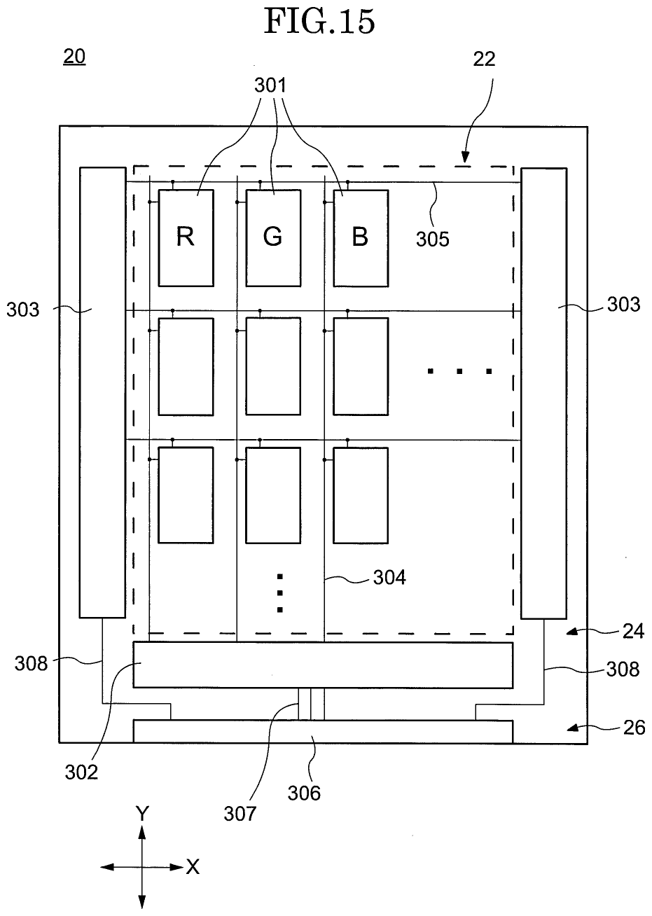

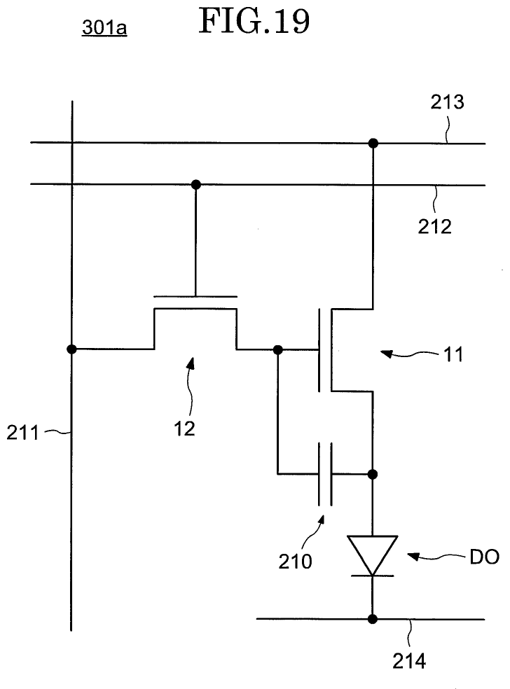

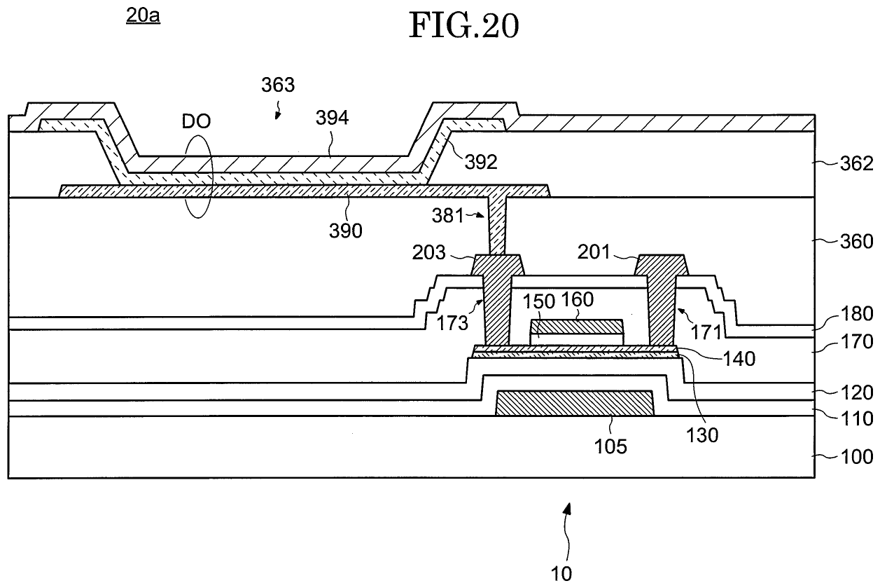

A display device using a semiconductor device according to an embodiment of the present invention will be described with reference to FIG. 19 and FIG. 20. A configuration in which each semiconductor device described in the first embodiment and the second embodiment is applied to an organic EL display device circuit will be described in the embodiments described below. Since the outline and the circuit configuration of a display device 20a are the same as those shown in FIG. 14 and FIG. 15, description thereof will be omitted.

### [Pixel Circuit of Display Device]

FIG. 19 is a circuit diagram showing a pixel circuit 301a of the display device 20a according to an embodiment of the present invention. The pixel circuit 301a includes elements such as a driving transistor 11, a select transistor 12, a storage capacitor 210, and a light-emitting element DO, as shown in FIG. 19.

The driving transistor 11 and the select transistor 12 have the same configuration as that of the semiconductor device 10. The source electrode of the select transistor 12 is connected to a signal line 211, and the gate wiring of the select transistor 12 is connected to a gate line 212. A source electrode of the driving transistor 11 is connected to an anode power line 213, and a drain electrode of the driving transistor 11 is connected to one end of the light-emitting element DO. The other end of the light-emitting element DO is connected to a cathode power line 214. A gate wiring of the driving transistor 11 is connected to a drain electrode of the select transistor 12. The storage capacitor 210 is connected to the gate wiring and the drain electrode of the driving transistor 11. A gradation signal that determines the emission intensity of the light-emitting element DO is supplied to the signal line 211. A signal for selecting a pixel row to which the gradation signal is written is supplied to the gate line 212.

### [Cross-Sectional Structure of Display Device]

FIG. 20 is a cross-sectional view showing an outline of the display device 20a according to an embodiment of the present invention. Although a configuration of the display device 20a shown in FIG. 20 is similar to that of the display device 20 shown in FIG. 17, the configuration above the insulating layer 360 is different between the display device 20 and the display device 20a. Hereinafter, among the configurations of the display device 20a shown in FIG. 20, the same configurations as those of the display device 20 shown in FIG. 17 will be omitted, and differences between the two will be described.

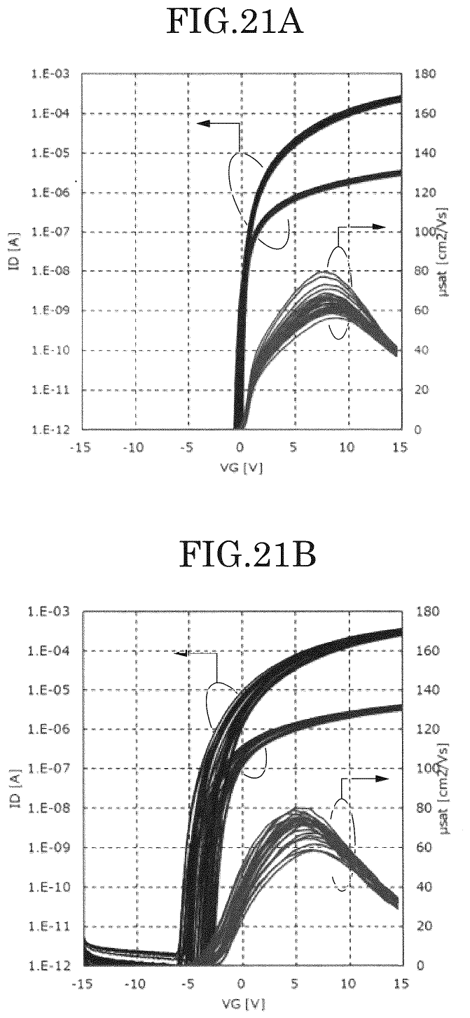

The display device 20a has the pixel electrode 390, a light-emitting layer 392, and a common electrode 394 above the insulating layer 360, as shown in FIG. 21. The light-emitting element DO is composed of the pixel electrode 390, the light-emitting layer 392, and the common electrode 394. The pixel electrode 390 is arranged on the insulating layer 360 and inside the opening 381. In this case, an insulating layer 362 is called a bank, a rib, or the like, and has a role of defining a light-emitting region. The insulating layer 362 is arranged on the pixel electrode 390. An opening 363 is arranged in the insulating layer 362. The opening 363 corresponds to the light-emitting region. The light-emitting layer 392 and the common electrode 394 are arranged on the pixel electrode 390 exposed by the opening 363. The pixel electrode 390 and the light-emitting layer 392 are arranged individually for each pixel. On the other hand, the common electrode 394 is arranged in common to the plurality of pixels. Different materials are used for the light-emitting layer 392 depending on the display color of the pixel.

The configurations in which the semiconductor devices described in the first embodiment and the second embodiment are respectively applied to the liquid crystal display device and the organic EL display device have been exemplified in the third embodiment and the fourth embodiment. However, the semiconductor devices described in the first embodiment and the second embodiment may be applied to a display device other than these display devices (for example, a self-luminous display device other than the organic EL display device or an electronic paper type display device). In addition, the above-described semiconductor device can be applied from a medium-sized display device to a large-sized display device without any particular limitation.

### Example

### [Electrical Characteristics of Semiconductor Device]

FIG. 21A is a diagram showing the electrical characteristics of the semiconductor device 10 according to an embodiment of the present invention. FIG. 21B is a diagram showing the electrical characteristics of a semiconductor device according to a comparative example. Specifically, FIG. 21B corresponds to the electrical characteristics of the semiconductor device 10 shown in FIG. 1 having a structure in which the metal oxide layer 130 is omitted. In addition, FIG. 21A and FIG. 21B respectively show a plurality of electrical characteristics obtained by measuring a plurality of semiconductor devices.

The electrical characteristics shown in FIG. 21A and FIG. 21B are measured as follows.
Size of the channel region CH: W/L=4.5 μm/3.0 μm
Source-drain voltage: 0.1 V, 10 V
Gate voltage: −15 V to +15 V
Measurement environment: room temperature, dark room

Id-Vg characteristics and the field-effect mobility (μsat) in the saturated region are shown in FIG. 21A and FIG. 21B as the electrical characteristics of the semiconductor device. The vertical axis representing the drain current (Id) is shown on the left side of the graph as indicated by the arrow in the graph of FIG. 21A and FIG. 21B. In addition, the vertical axis representing the field-effect mobility calculated from the drain current is shown on the right side of the graph. The horizontal axis represents the gate voltage supplied to each semiconductor device.

The Id-Vg characteristics in the semiconductor device 10 of the first embodiment shows so-called normally-off characteristics in which the drain current Id starts to flow when the gate voltage Vg is substantially 0 V, as shown in FIG. 21A. The drain current varies little and is very stable whether the source-drain voltage is 0.1 V or 10 V. The average value of the threshold voltage (Vth) obtained from the plurality of Id-Vg characteristics was 0.30 V. In addition, the average value of the intrinsic mobility obtained from the plurality of Id-Vg characteristics was 23.7 cm²/Vs and the average value of the field-effect mobility was 37.6 cm²/Vs.

On the other hand, the Id-Vg characteristics of the semiconductor device of the comparative example showed so-called normally-on characteristics in which the threshold voltage is shifted in the negative direction and the drain current Id starts to flow when the gate voltage Vg is 0 V or less, as shown in FIG. 21B. The average value of the threshold voltages obtained from the plurality of Id-Vg characteristics was-3.59 V. In addition, the drain current showed a high value on average, although there was some variation, and no significant problem was observed in the switching characteristics. The average value of the intrinsic mobility obtained from the plurality of Id-Vg characteristics was 19.5 cm²/Vs and the average value of the field-effect mobility was 30.8 cm²/Vs.

In this case, the average value of the width (ΔL/2) of the overlapping region OL in the semiconductor device 10 of the first embodiment was 0.82 μm, and the average value of the width of the overlapping region OL in the semiconductor device of the comparative example was 1.50 μm. That is, it was found that the width of the overlapping region OL varies by nearly twice depending on the presence or absence of the metal oxide layer 130 shown in FIG. 1. That is, it has been found that arranging the metal oxide layer 130 is very effective in reducing the width of the overlapping region OL.

In addition, the design channel length is 3.0 μm and the width of the overlapping region OL is 1.5 μm in the semiconductor device of the comparative example, so it appears that there is no channel region CH from the calculation. However, in practice, there is an error in the design channel length, and the above-described width of the overlapping region OL is just an averaged value, so in practice, the channel region CH does not completely disappear.

The width of the overlapping region OL can be determined in various ways. An example in which the overlapping region OL is obtained from the relationship between the design channel length and a channel resistance R of the transistor when applying different gate voltages is shown in the present embodiment.

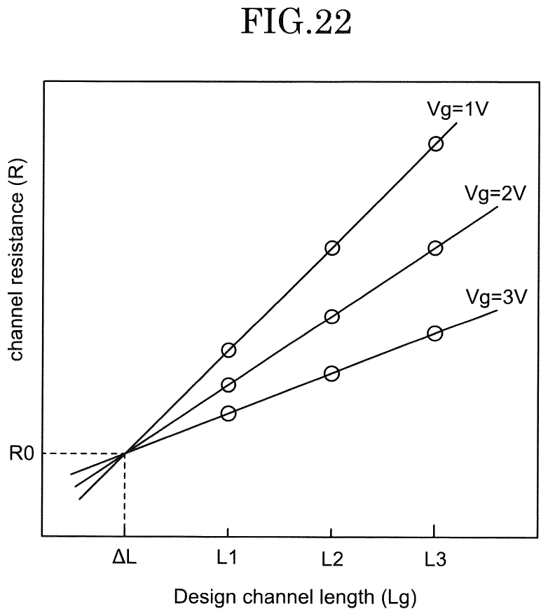

FIG. 22 is a diagram exemplifying a relationship of the channel resistance (R) to the design channel length (channel length on layout) (Lg) of the transistor for differing gate voltages (Vg). Specifically, the horizontal axis represents the design channel length (Lg), and the vertical axis represents the channel resistance (R) in FIG. 22. Each channel resistance (R) in the case where 1 V, 2 V, or 3V is applied as the gate voltage (Vg) to each transistor whose design channel length (Lg) is L1, L2, or L3 is shown in FIG. 22. There is a linear relationship between the design channel length (Lg) and the channel resistance (R) in each gate voltage (Vg), as shown in FIG. 22.

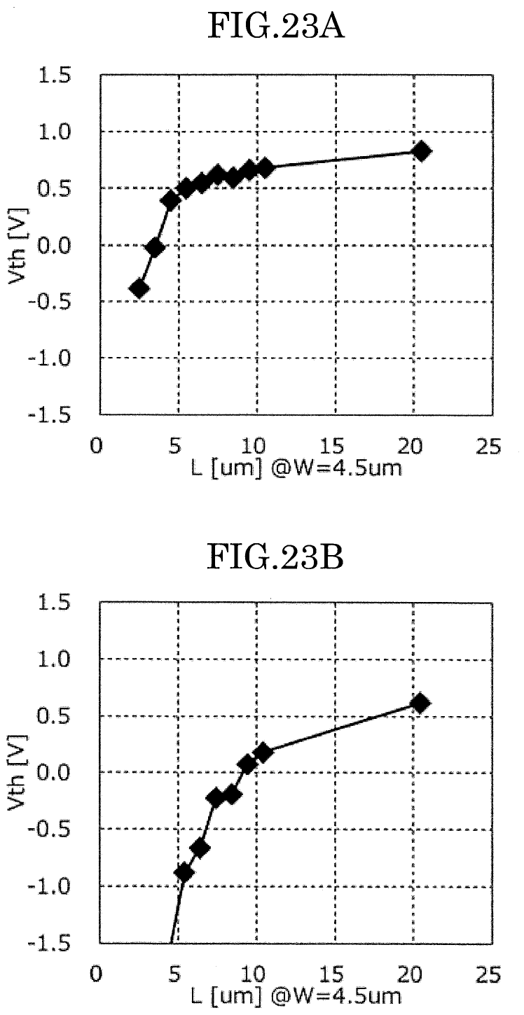

Here, in the case where a straight line indicating each linear relationship is extrapolated in a direction in which Lg becomes smaller, a point where each extrapolation line intersects appears. This intersection is the point at which the effective channel length (Leff) is zero in the measured transistor system. In this case, when the X coordinate of the intersection is ΔL and the Y coordinate is R0, ΔL corresponds to the width of the overlapping region OL, and R0 corresponds to the series resistance generated by the overlapping region OL. A relationship of Leff=Lg−ΔL is established between the effective channel length (Leff) and the design channel length (Lg). In the case where the transistor is symmetrical in the first direction (direction D1) as shown in FIG. 1, the sum of a source-side overlapping region OLS and a drain-side overlapping region OLD is ΔL. That is, a relationship of OLS=OLD=ΔL/2 is established between the source-side overlapping region OLS and the drain-side overlapping region OLD. Next, FIG. 23A is a diagram showing a dependence of the threshold voltage on the channel length in the semiconductor device 10 according to an embodiment of the present invention. FIG. 23B shows a dependence of the threshold voltage on the channel length in the semiconductor device of the comparative example described above. In this case, the channel width (W) of each semiconductor device was set to 4.5 μm.

It has been found that the semiconductor device 10 of the present embodiment exhibits stable switching characteristics with almost no change in the threshold voltage in a channel length range of 4 μm or more and 20 μm or less, as shown in FIG. 23A. In addition, it has been found that even when the channel length is in a range of 4 μm or less (for example, 2.5 μm or more and 4 μm or less), a threshold voltage of −0.4 V or more can be secured. That is, a stable threshold voltage is obtained regardless of the channel length, and even if the channel length becomes 4 μm or less, the threshold voltage is not shifted in a large negative direction in the semiconductor device 10 of the present embodiment. On the other hand, the semiconductor device of the comparative example showed a negative shift of the threshold voltage in a range where the channel length was 10 μm or less, as shown in FIG. 23B.

The difference in the electrical characteristics seen in FIG. 23A and FIG. 23B is considered to be due to the width (ΔL/2) of the overlapping region OL. That is, since the width of the overlapping region OL can be suppressed to 1 μm or less, the difference between the design channel length (Lg) and the effective channel (Leff) is small in the semiconductor device 10 of the present embodiment. Therefore, the dependence of the threshold voltage on the channel length tends to be close to the dependence of the threshold voltage on the design channel length. On the other hand, since the width of the overlapping region OL is longer than that of the present embodiment, the influence of the width of the overlapping region OL becomes more apparent as the design channel length becomes shorter, in the semiconductor device of the comparative example.

As described above, it can be said that setting the width of the overlapping region OL to 1 μm or less is important in suppressing the deterioration of the electrical characteristics of the semiconductor device, particularly, the shift of the threshold voltage in the negative direction. In order to suppress the width of the overlapping region OL to 1 μm or less, it is effective to increase the oxygen content of the layer underlying the oxide semiconductor layer 140, that is, the insulating layer 120. Further, in addition to increasing the oxygen content of the insulating layer 120, it is also desirable to arrange the metal oxide layer 130 between the insulating layer 120 and the oxide semiconductor layer 140.

Each of the embodiments described above as an embodiment of the present invention can be appropriately combined and implemented as long as no contradiction is caused. Further, the addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a first insulating layer;
a metal oxide layer mainly composed of aluminum on the first insulating layer;
an oxide semiconductor layer having a polycrystalline structure on the metal oxide layer;
a gate insulating layer on the oxide semiconductor layer;
a gate electrode on the gate insulating layer; and
a second insulating layer on the gate electrode, wherein
the metal oxide layer and the oxide semiconductor layer are both patterned, and
the oxide semiconductor layer has a first region in contact with the gate insulating layer and a second region continuous with the first region in a first direction and in contact with the gate insulating layer and the second insulating layer.

2. The semiconductor device according to claim 1, wherein
the second insulating layer contacts the gate electrode, the gate insulating layer and the oxide semiconductor layer.

3. The semiconductor device according to claim 1, wherein
the second insulating layer has a stacked structure including a silicon nitride layer and a silicon oxide layer.

4. The semiconductor device according to claim 1, wherein
the first region is a channel region of a transistor, and
the second region is a region of lower resistance than the channel region.

5. The semiconductor device according to claim 1, wherein
the metal oxide layer and the oxide semiconductor layer have the same pattern shape.

6. The semiconductor device according to claim 1, wherein
the gate insulating layer and the gate electrode have the same pattern shape.

7. The semiconductor device according to claim 1, wherein
the oxide semiconductor layer contains at least two or more metallic elements including indium, and
a ratio of indium to the at least two or more metallic elements is 50% or more.

8. The semiconductor device according to claim 1, wherein
a width in the first direction of a portion of the second region in contact with the gate insulating layer is 1 μm or less.

9. The semiconductor device according to claim 8, wherein
a width of the gate electrode in the first direction is 4 μm or less.

10. The semiconductor device according to claim 8, wherein
a width of the gate electrode in the first direction is 1 μm or more and greater than twice a width in the first direction of the portion of the second region in contact with the gate insulating layer.

11. A display device comprising a plurality of pixels, each of the plurality of pixels comprising the semiconductor device according to 5 claim 1.
